(19) United States
(12) Patent Application Publication
(10) Pub. No.: US 2024/0223155 A1
(43) Pub. Date: Jul. 4, 2024

(54) ACOUSTIC RESONATOR HAVING SYMMETRIC COATING MATERIAL FOR IMPROVED COUPLING

(71) Applicant: Murata Manufacturing co., Ltd., Nagaokakyo-shi (JP)

(72) Inventors: John KOULAKIS, Los Angeles, CA (US); Drew Morosin, Oxnard, CA (US)

(21) Appl. No.: 18/394,448

(22) Filed: Dec. 22, 2023

Related U.S. Application Data
(60) Provisional application No. 63/477,987, filed on Dec. 30, 2022.

(51) Int. Cl. H03H 9/145; H03H 3/08; H03H 9/02; H03H 9/25

(52) U.S. Cl. CPC H03H 9/145; H03H 3/08; H03H 9/02543; H03H 9/25

(57) ABSTRACT

An acoustic resonator is provided that includes a substrate; a piezoelectric layer having first and second surfaces that oppose each other with the second surface coupled to the substrate either directly or via one or more intermediate layers. The piezoelectric layer includes a diaphragm over a cavity extending in at least one of the substrate and the one or more intermediate layers. An interdigital transducer (IDT) is disposed at the piezoelectric layer and has interleaved fingers on the diaphragm. Moreover, first and second dielectric layers are disposed on opposing surfaces of the diaphragm, where the first and second dielectric layers have a first thickness and the piezoelectric layer has a second thickness greater than the first thickness. The first and second dielectric layers each comprise one of ZnS, HfN, HfO₂, ZnO and Ta₂O₅, to improve an electrotechnical coupling of the acoustic resonator.

### CROSS REFERENCE TO RELATED APPLICATIONS

The current application claims priority to U.S. Patent Provisional Application No. 63/477,987, filed Dec. 30, 2022, the entire contents of which are hereby incorporated by reference.

### TECHNICAL FIELD

This disclosure relates to radio frequency filters using acoustic wave resonators, and specifically to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

### SUMMARY

Accordingly, as described herein, an acoustic resonator and filter device incorporating the same is provided having a symmetric coating configuration to provide improved coupling.

In an exemplary aspect an acoustic resonator is provided that includes a substrate; a piezoelectric layer having first and second surfaces that oppose each other with the second surface coupled to the substrate either directly or via one or more intermediate layers, the piezoelectric layer including a diaphragm over a cavity extending in at least one of the substrate and the one or more intermediate layers; an interdigital transducer (IDT) at the piezoelectric layer and having interleaved fingers on the diaphragm; and first and second dielectric layers on opposing surfaces of the diaphragm. In this aspect, each of the first and second dielectric layers have a first thickness and the piezoelectric layer has a second thickness greater than the first thickness, and the first and second dielectric layers each comprise one of ZnS, HfN, HfO₂, ZnO and Ta₂O₅. Moreover, according to the exemplary aspect, the first thickness is between 0.25% and 22% of the second thickness when the first and second dielectric layers are ZnS, the first thickness is between 0.25% and 12% of the second thickness when the first and second dielectric layers are HfN, the first thickness is between 0.25% and 21% of the second thickness when the first and second dielectric layers are HfO₂, the first thickness is between 0.25% and 24% of the second thickness when the first and second dielectric layers are ZnO, and the first thickness is between 0.25% and 21% of the second thickness when the first and second dielectric layers are Ta₂O₅.

In another exemplary aspect, the IDT is on the first surface of the piezoelectric layer and the first dielectric layer is on and between the interleaved fingers of the IDT. Alternatively, the IDT is on the second surface of the piezoelectric layer and the second dielectric layer is on and between the interleaved fingers of the IDT.

In another exemplary aspect, the first and second dielectric layers comprises a symmetric coating thickness on the opposing surfaces of the diaphragm.

In another exemplary aspect, the one or more intermediate layers comprise silicon dioxide.

In another exemplary aspect, the acoustic resonator is configured for operating in a first-order antisymmetric (A1) mode and the first and second dielectric layers are configured for a predetermined coupling of the acoustic resonator operating in the A1 mode. Moreover, the piezoelectric layer can comprise lithium niobate having Euler angles [0°, 30°, 0° ].

In another exemplary aspect, the piezoelectric layer and the IDT are configured such that a radio frequency signal applied to the IDT excites a primary shear acoustic mode in the diaphragm that is a bulk shear mode where acoustic energy propagates along a direction substantially orthogonal to the first and second surfaces of the piezoelectric layer and transverse to a direction of electric field created by the IDT.

In another exemplary aspect, the first thickness of the first and second dielectric layers and the second thickness of the piezoelectric layer are each measured in a direction substantially orthogonal to the opposing surfaces of the diaphragm.

In yet another exemplary aspect, an acoustic resonator is provided that includes a piezoelectric layer having first and second surfaces that oppose each other; an interdigital transducer (IDT) at the first surface of the piezoelectric layer; a first dielectric layer on the first surface of the piezoelectric layer and on and between interleaved fingers of the IDT; and a second dielectric layer on the second surface of the piezoelectric layer that is opposite to the first dielectric layer. In this aspect, each of the first and second dielectric layers comprise a same material comprising one of ZnS, HfN, HfO₂, ZnO and Ta₂O₅, where the first and second dielectric layers each have a same first thickness to form a symmetric coating configuration on the piezoelectric layer. Moreover, the piezoelectric layer has a second thickness greater than the first thickness. According to the exemplary aspect, the first thickness is between 0.25% and 22% of the second thickness when the first and second dielectric layers are ZnS, the first thickness is between 0.25% and 12% of the second thickness when the first and second dielectric layers are HfN, the first thickness is between 0.25% and 21% of the second thickness when the first and second dielectric layers are HfO₂, the first thickness is between 0.25% and 24% of the second thickness when the first and second dielectric layers are ZnO, and the first thickness is between 0.25% and 21% of the second thickness when the first and second dielectric layers are Ta₂O₅.

In yet another exemplary aspect, a method is provided for fabricating an acoustic resonator device having a dielectric layer configured to optimize electromechanical coupling. In this aspect, the method includes attaching a piezoelectric layer to a substrate via one or more intermediate layers to form a diaphragm over a cavity in the one or more intermediate layers; forming an interdigital transducer (IDT) at the piezoelectric layer; depositing first and second dielectric layers on opposing surfaces of the diaphragm, such that at least one of the first and second dielectric layers is on and between interleaved fingers of the IDT, with the first and second dielectric layers formed of a same material comprising one of ZnS, HfN, HfO₂, ZnO and Ta₂O₅; and trimming the first and second dielectric layers to form a symmetric coating on the diaphragm, such that the first and second dielectric layers have a first thickness that is less than a second thickness of the piezoelectric layer. In this aspect, the trimming of first and second dielectric layers provides for the first thickness to be between 0.25% and 22% of the second thickness when the first and second dielectric layers are ZnS, the trimming of first and second dielectric layers provides for the first thickness to be between 0.25% and 12% of the second thickness when the first and second dielectric layers are HfN, the trimming of first and second dielectric layers provides for the first thickness to be between 0.25% and 21% of the second thickness when the first and second dielectric layers are HfO₂, the trimming of first and second dielectric layers provides for the first thickness to be between 0.25% and 24% of the second thickness when the first and second dielectric layers are ZnO, and the trimming of first and second dielectric layers provides for the first thickness to be between 0.25% and 21% of the second thickness when the first and second dielectric layers are Ta₂O₅.

The above simplified summary of example aspects serves to provide a basic understanding of the present disclosure. This summary is not an extensive overview of all contemplated aspects and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplarily pointed out in the claims.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and two schematic cross-sectional views of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6 illustrates a graph of the coupling of an acoustic resonator as a function of frontside dielectric thickness/plate thickness in which the dielectric is silicon dioxide.

FIG. 7 shows a graph of the coupling of two acoustic resonators as a function of each of their frontside dielectric thickness/plate thickness in which the dielectrics are silicon dioxide and silicon nitride.

FIG. 8 shows a graph of the coupling of a plurality of acoustic resonators implementing specific dielectric materials and set thicknesses according to an exemplary aspect.

FIG. 9 illustrates a flowchart of a method of manufacturing an acoustic resonator device as described herein according to an exemplary aspect.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed acoustic resonator, filter device and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

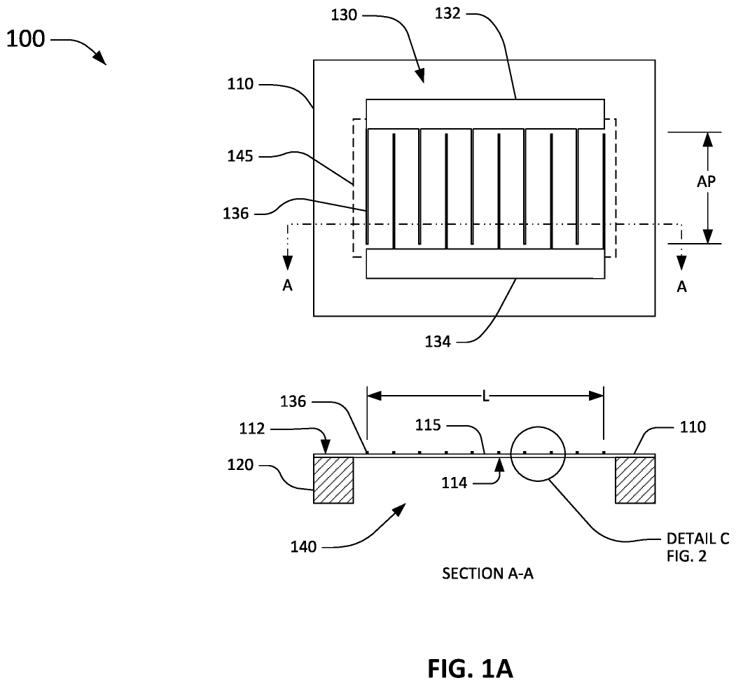

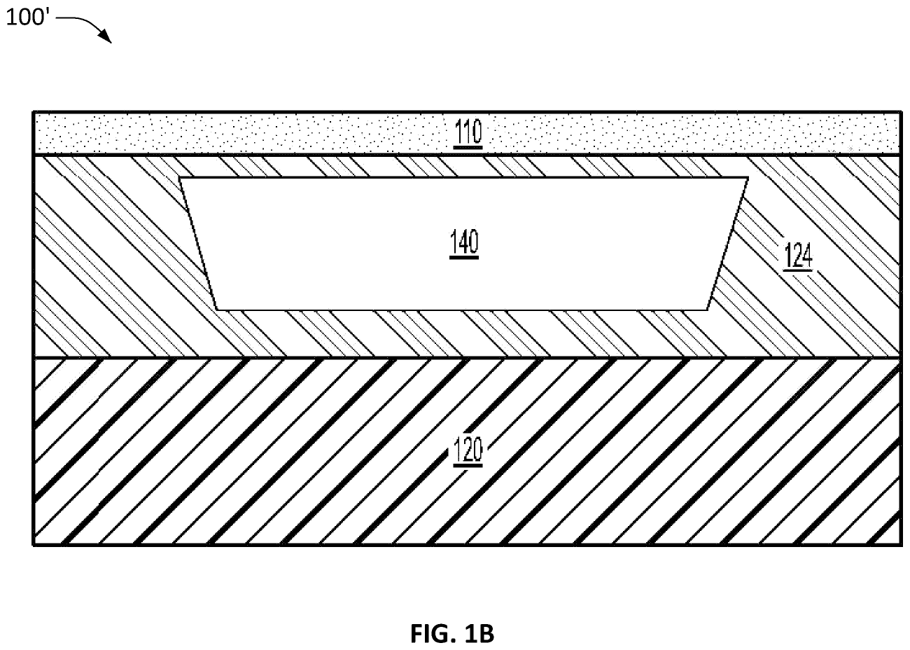

FIG. 1A shows a simplified schematic top view and orthogonal cross-sectional views of an acoustic resonator device, namely a transversely excited film bulk acoustic resonator (XBAR) 100. XBAR resonators, such as the resonator 100, may be used in a variety of RF filters including band-reject filters, band-pass filters, duplexers, and multiplexers. XBARs are particularly suited for use in filters for communications bands with frequencies above 3 GHz.

In general, the XBAR 100 is made up of a thin film conductor pattern formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and parallel to each other. For example, to the manufacturing variances result from the deposition process, the front side 112 and back side 114 may have undulations of the surface as would be appreciated to one skilled in the art.

According to an exemplary aspect, the piezoelectric layer is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0° ] is commonly referred to as “120° rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110, such as one or more intermediate layers above or in the substrate. In other words, the back side 114 of the piezoelectric layer 110 can be coupled or connected either directly or indirectly, via one or more intermediate layers (e.g., a dielectric layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

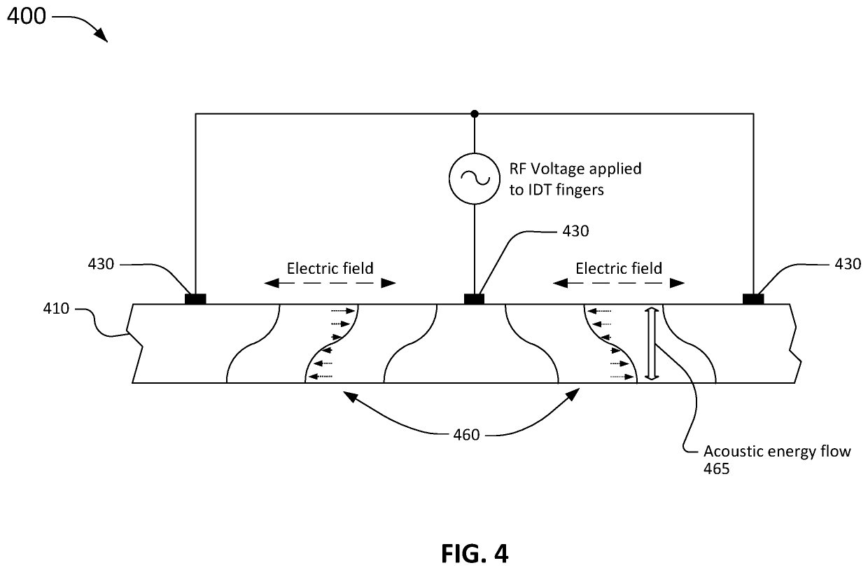

The first and second busbars 132, 134 are configured as the terminals of the XBAR 100. In operation, a radio frequency or microwave signal applied between the two busbars 132, 134 of the IDT 130 primarily excites an acoustic mode within the piezoelectric layer 110. As will be discussed in further detail, the primarily excited acoustic mode is a bulk shear mode or bulk acoustic wave where acoustic energy of a bulk shear acoustic wave is excited in the piezoelectric layer 110 by the IDT 130 and propagates along a direction substantially and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to as an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the measurement of the aperture AP of the interleaved fingers of the IDT 130. As used herein through the disclosure, area is referenced in μm² and be considered the area in the X-Y plane of the IDT, for example. Thus, the area of the XBAR 100 may be adjusted based on design choices, as described below, thereby adjusting the overall capacitance of a particular XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example SiO₂, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other.

Moreover, in the example of FIG. 1B, the cavity 140 is defined on all sides by the dielectric layer 124. However, in other exemplary embodiments, one or more sides of the cavity 140 may be defined by the substrate 120 or the piezoelectric layer110. In the example of FIG. 1B, the cavity 140 has a trapezoidal shape. However, as noted above, cavity shape is not limited and may be rectangular, oval, or other shapes.

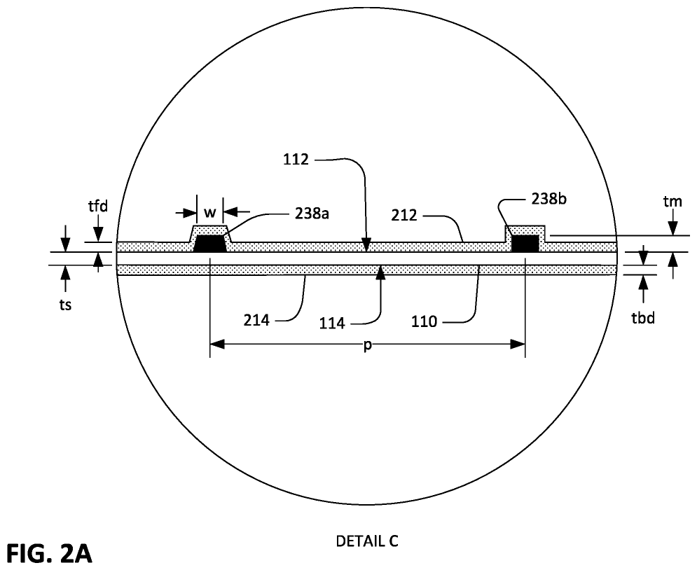

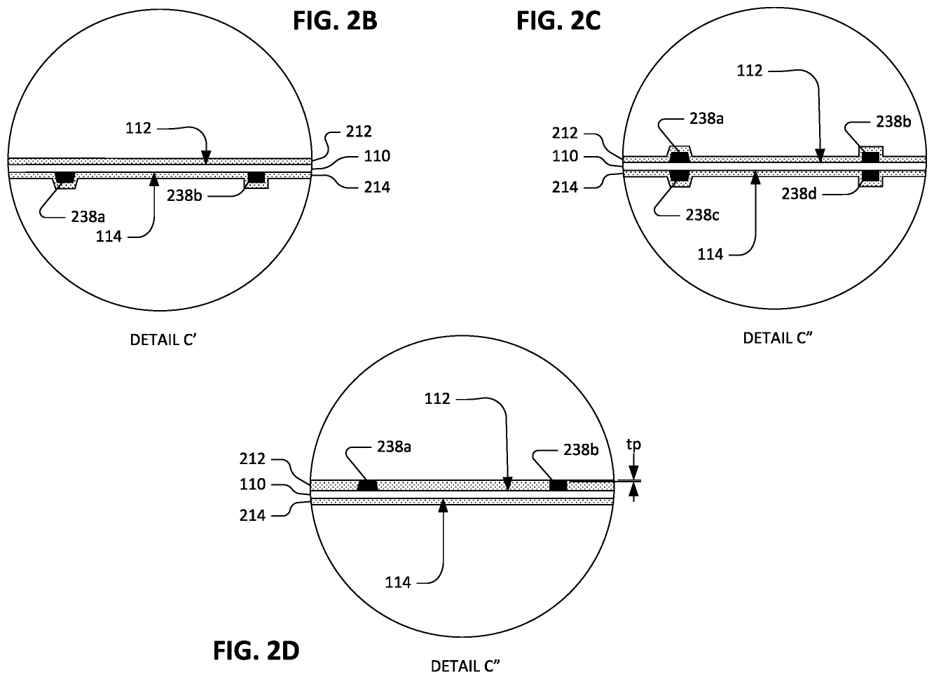

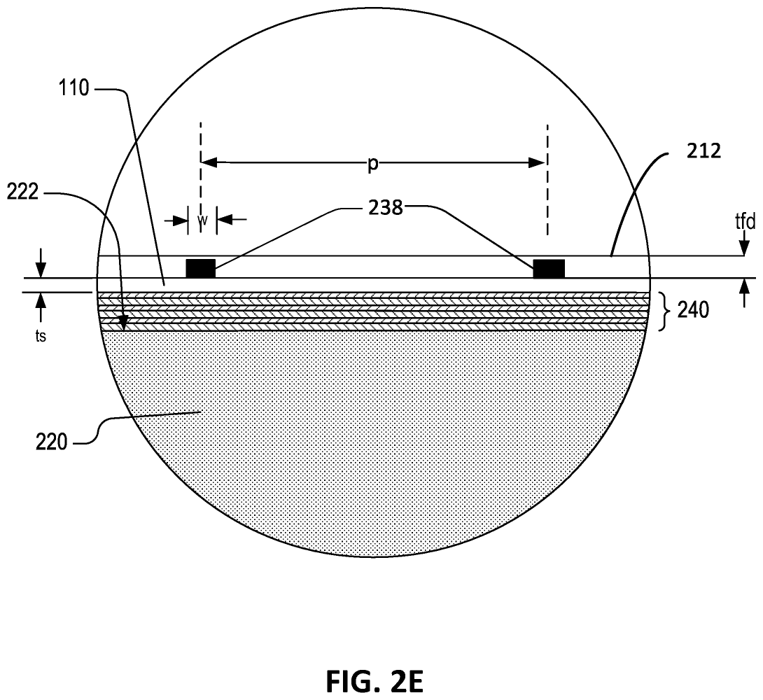

FIG. 2A shows a detailed schematic cross-sectional view of the XBAR 100 of FIG. 1A or 1B. The piezoelectric layer 110 is a single-crystal layer of piezoelectrical material having a thickness ts. ts may be, for example, 100 nm to 1500 nm. When used in filters for 5G NR and Wi-Fi™ bands from 3.4 GHZ to 7 GHZ, the thickness ts may be, for example, 150 nm to 500 nm.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. Either or both of the front side and back side dielectric layers 212, 214 may be formed of multiple layers of two or more materials according to various exemplary aspects. As described in detail below, the first and second dielectric layers (dielectric coating layers or materials) can be formed on the opposing surfaces to provide a symmetric coating of the acoustic resonator. Moreover, the particular material and thickness of these dielectric layers can be set to improve the electromechanical coupling of the acoustic resonator while minimizing thickness of the device.

The IDT fingers 238a, 238b may be aluminum, substantially aluminum alloys, copper, substantially copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1) of the IDT may be made of the same or different materials as the fingers. The cross-sectional shape of the IDT fingers may be trapezoidal (finger 238a), rectangular (finger 238b) or some other shape in various exemplary aspects.

Dimension p is the center-to-center spacing between adjacent IDT fingers, such as the IDT fingers 238a, 238b in FIGS. 2A-2C. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, according to an exemplary aspect as will be discussed in more detail below, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A, 2B, and 2C, has a width w measured normal to the long direction of each finger. The width w may also be referred to herein as the “mark.” In general, the width of the IDT fingers may be constant over the length of the IDT, in which case the dimension w may be the width of each IDT finger. However, in an exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction parallel to the length L of the IDT, as defined in FIG. 1A.

In general, the IDT of an XBAR differs substantially from the IDTs used in surface acoustic wave (SAW) resonators, primarily in that IDTs of an XBAR excite a shear thickness mode, as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to deal and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM XBAR). The SM XBAR includes a piezoelectric layer 110 and an IDT (including a pair of IDT fingers 238) with a dielectric layer 212 disposed on the piezoelectric layer 110 and IDT fingers 238. The piezoelectric layer 110 has parallel front and back surfaces similar to the configurations described above. Dimension ts is the thickness of the piezoelectric layer 110. The width of the IDT fingers 238 is dimension w, thickness of the IDT fingers is dimension tm, and the IDT pitch is dimension p. It is noted that IDT fingers 238 can generally correspond to fingers 238a and 238b as described above.

In contrast to the XBAR devices shown in FIG. 1, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 238a and 238b, may be disposed on a surface of the front side 112 of the piezoelectric layer 110. Alternatively, IDT fingers, such as IDT finger 238a and 238b, may be disposed in grooves formed in the surface of the front side 112. The grooves may extend partially through the piezoelectric layer. Alternatively, the grooves may extend completely through the piezoelectric layer.

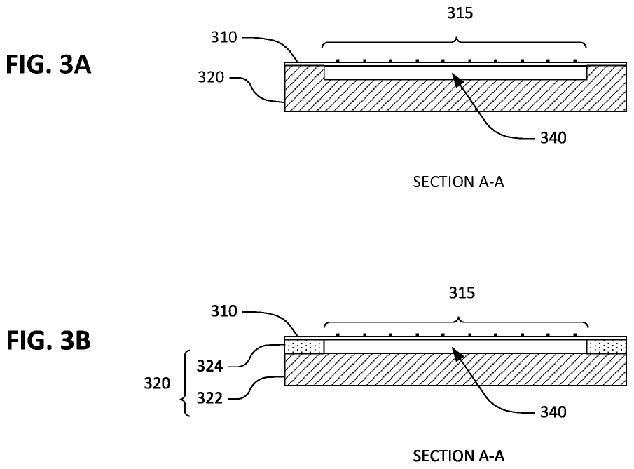

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field,” to excite a primary shear acoustic mode I the diaphragm of the acoustic resonator. Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465. Effectively, the primary shear acoustic mode is a bulk shear mode where acoustic energy propagates along a direction substantially orthogonal to the first and second surfaces of the piezoelectric layer and transverse to a direction of the electric field created by the IDT.

An acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

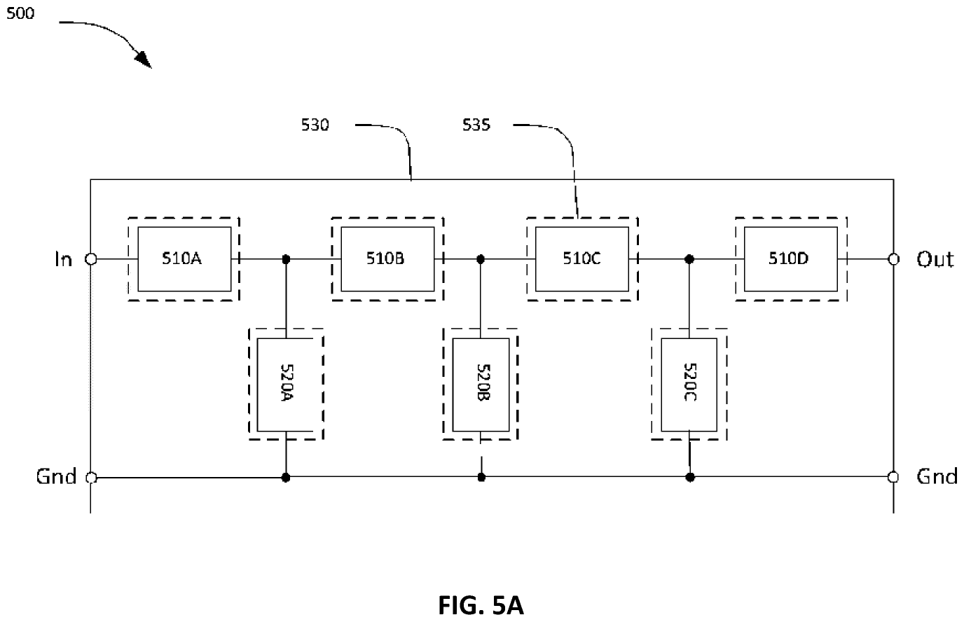

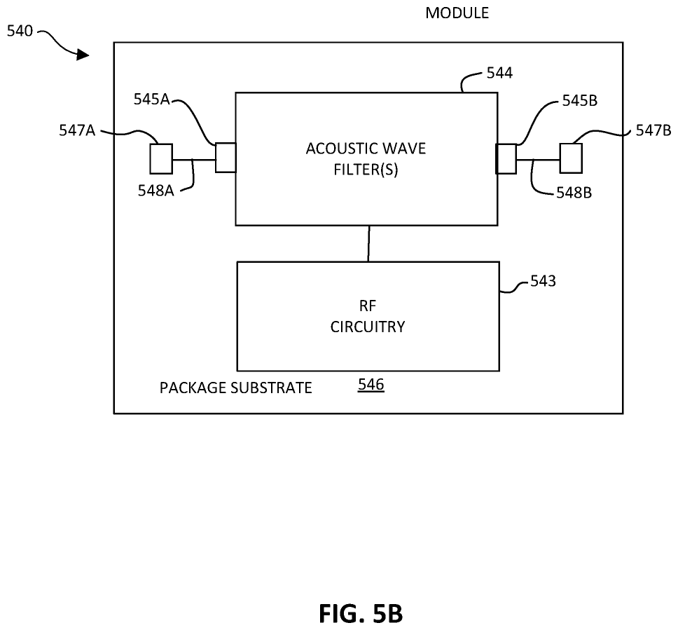

FIG. 5A is a schematic circuit diagram and layout for a high frequency band-pass filter 500 using XBARs, such as the general XBAR configuration 100 described above, for example. The filter 500 has a conventional split ladder filter architecture including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least three shunt resonators, such as shunt resonators 520A, 50B and 502C, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. It is noted that for a split ladder, the filter may have more or fewer than seven total resonators, more or fewer than four series resonators, and more or fewer than three shunt resonators. Typically, all of the series resonators are connected in series between an input and an output of the filter. All of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 are formed on at least one, and in some cases a single, piezoelectric layer 530 of piezoelectric material bonded to a silicon substrate (not visible). However, in alternative aspects, the individual resonators may each be formed on a separate piezoelectric layer bonded to a separate substrate, for example. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500. In particular, and as described in detail below, the specific resonators may have a symmetric coating on the piezoelectric formed of a predetermined material to achieve a particular coupling parameter requirement (i.e., the coupling coefficient k²).

According to an exemplary aspect, each of the series resonators 510A, 510B, 510C and 510D and the shunt resonators 520A, 520B and 520C can have an XBAR configuration as described above with respect to FIGS. 1-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrates a radio frequency module 540 that includes one or more acoustic wave filters 544 according to an exemplary aspect. The illustrated radio frequency module 540 also includes radio frequency (RF) circuitry (or circuit) 543. In an exemplary aspect, the acoustic wave filters 544 may include one or more of filter 500 including XBARs, as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

Thus, according to the exemplary aspect, a radio frequency module may incorporate a radio frequency (RF) filter that in turn incorporates multiple XBAR devices connected as a ladder filter circuit. Moreover, the dominant parameter that determines the resonance frequency of an XBAR is the thickness of the piezoelectric layer or membrane (e.g., the diaphragm) of the resonator. Resonance frequency also depends, to a lesser extent, on the pitch and width, or mark, of the IDT fingers. Many filter applications require resonators with a range of resonance and/or anti-resonant frequencies beyond the range that can be achieved by varying the pitch of the IDTs. In an example, U.S. Pat. No. 10,491,291, the contents of which are hereby incorporated by reference, describes the use of a dielectric frequency setting layer deposited between and/or over the fingers of the fingers of the IDTs of shunt resonators to lower the resonant frequencies of the shunt resonators with respect to the resonant frequencies of the series resonators.

As described above, in an exemplary aspect, the acoustic resonators, such as resonator 100 illustrated in FIG. 2A includes a dielectric layer 214 (either planarized or conformal) that is over and between the IDT fingers 238a and 238b of the IDT 130. Moreover, in additional exemplary aspects, such as those described in FIGS. 2B to 2D, a pair of dielectric layers (e.g., dielectric layers 212 and 214) can be disposed on opposing surfaces of the diaphragm. In such instances, these dielectric layers can be considered coating materials or coating layers for the IDT in an exemplary aspect. As further described above, the dielectric layers 212 and/or 214 (e.g., the coating layers) can be silicon dioxide and these resonators can be implemented to form the ladder filter 500 as shown in FIG. 5A as also described above.

In general, filter devices (e.g., ladder filters) with high bandwidth, for example “full band” WiFi®, require resonators with high coupling, which is generally considered the distance between resonance and anti-resonance, in order to maximize performance. On the other hand, the filter device performance will suffer if the resonators implemented therein do not provide for sufficient coupling. Resonators with lower coupling can be used as long as their coupling is above a minimum required, but there is a performance cost in terms of size, rejection, steepness, loss or combinations thereof.

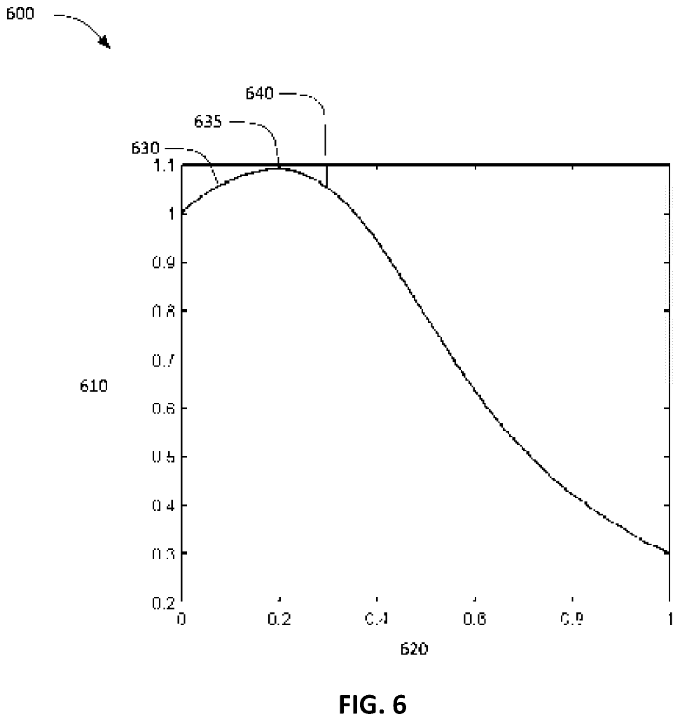

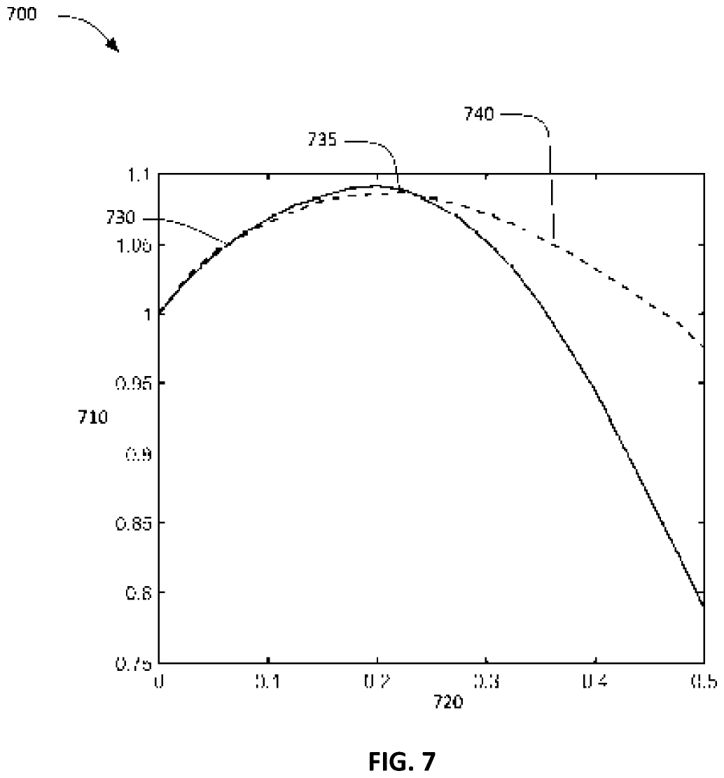

For purposes of describing FIGS. 6 and 7, resonator coupling is shown to be k²=(ƒα²−fr²)/(ƒα²), where k²= is the coupling, ƒα is the anti-resonant frequency and fr is the resonant frequency of the given acoustic resonator. In particular, FIG. 6 illustrates a graph 600 of the resonator coupling 610 as a function of frontside dielectric thickness to piezoelectric plate thickness 620 (e.g., tfd/ts as shown in FIGS. 2A-2D). The graph 600 can be provided as a result of a finite element method (FEM) simulation performed for an acoustic resonator having a piezoelectric layer thickness ts of 400 nm of Z-cut LiNbO3, a frontside dielectric thickness tfd of SiO2; IDT fingers being 10 nm thick metal electrodes with a 20 nm mark; and the interleaved fingers of the IDT having a pitch p=4 μm/scalefactor, where scalefactor=400 nm(ts)/total thickness(tfd+ts).

As shown in FIG. 6, there is a clearly pronounced maximum in coupling as thickness tfd is increased from zero to approximately 20 percent of the thickness ratio tfd/ts. In particular, the maximum coupling 635 is at approximately 20 percent oxide thickness tfd/ts and provides approximately 10 percent increase in coupling. As this ratio further increases, the coupling drops sharply. For example, changes of about 5 percent of coupling are shown at 630 and 640, which are approximately 5 percent and 30 percent oxide thickness tfd/ts.

FIG. 7 illustrates a graph 700 of the coupling 710 of two acoustic resonators as a function of each of their frontside oxide thickness/plate thickness 720 (e.g., tfd/ts as shown in FIGS. 2A-2D). In particular, graph 700 is provided for two iterations of an acoustic resonators as shown in the exemplary aspects of FIGS. 1 to 3 described above. The data plots in graph 700 are the results of a FEM simulation performed for the acoustic resonators of graph 600 shown of FIG. 6 (shown above) as the solid line; and performed for an acoustic resonator having the same physical dimensions as that shown in FIG. 6, except that the material of the frontside dielectric is Si3N4, which has a higher a dielectric constant (than silicon dioxide) of ϵ=7.0 ϵ0.

As shown in FIG. 7, for the thickness tfd of Si3N4, there is a clearly pronounced maximum in coupling as thickness tfd is increased from zero to about 20 percent thickness tfd/ts. The maximum coupling 735 is at approximately 20 or 22 percent oxide thickness tfd/ts and provides approximately 10 percent increase in coupling. Above this value, coupling (shown as the dashed line) drops more slowly than for the silicon dioxide (SiO₂) dielectric shown in the solid line. Changes of about 5 percent of coupling are shown at 730 and 740, which are approximately 5 percent and 35 percent oxide thickness tfd/ts. There is an increase in coupling from about 1% to about 45% percent of tfd/ts.

In the data plots of graphs 600 and 700, the existence of a coupling coefficient k² has a maximum value at nonzero tfd of the oxide, which is due at least partially to the fact that total coupling of the acoustic resonator depends on the dielectric coefficient of the frontside dielectric as well as the piezoelectric coefficients of the piezoelectric layer or plate. The coupling coefficient k² is inversely proportional to the dielectric coefficient of the frontside dielectric. In some cases, the piezoelectric layer or plate (e.g., lithium niobate) has a dielectric constant (approximately or at 45) that is much greater than the dielectric constant for a frontside dielectric of SiO₂ (approximately or at 4), and as SiO₂ is added, the effective dielectric constant drops. This drop in dielectric constant from adding SiO₂ allows the coupling coefficient k² to rise at moderate SiO₂ thicknesses, such as between 1 and 40 percent thickness of the piezoelectric layer or plate. However, as the thickness of SiO₂ coating layer is further increased, the piezoelectricity portion dominates and the coupling coefficient k² drops rapidly.

For certain acoustic resonators, it is needed to increase (or target) the coupling coefficient while at the same time also reducing the overall thickness of the acoustic resonator. Thus, according to an exemplary aspect, an acoustic resonator is provided with symmetric coating layers, i.e., dielectric layers on opposing surfaces of the piezoelectric layer/diaphragm having the same thickness. Moreover, a material of the dielectric layers is selected to increase the coupling while also reducing the overall thickness of the acoustic resonator, i.e., by reducing the thicknesses of the respective first and second (e.g., top and bottom) dielectric layers. In particular, each of the dielectric layers (e.g., first and second dielectric layers 212 and 214 as described above) are formed of a same material, which can be one of zinc oxide (ZnO), zinc sulfide (ZnS), tantalum pentoxide (Ta₂O₅), hafnium nitride (HfN), and hafnium dioxide (HfO₂).

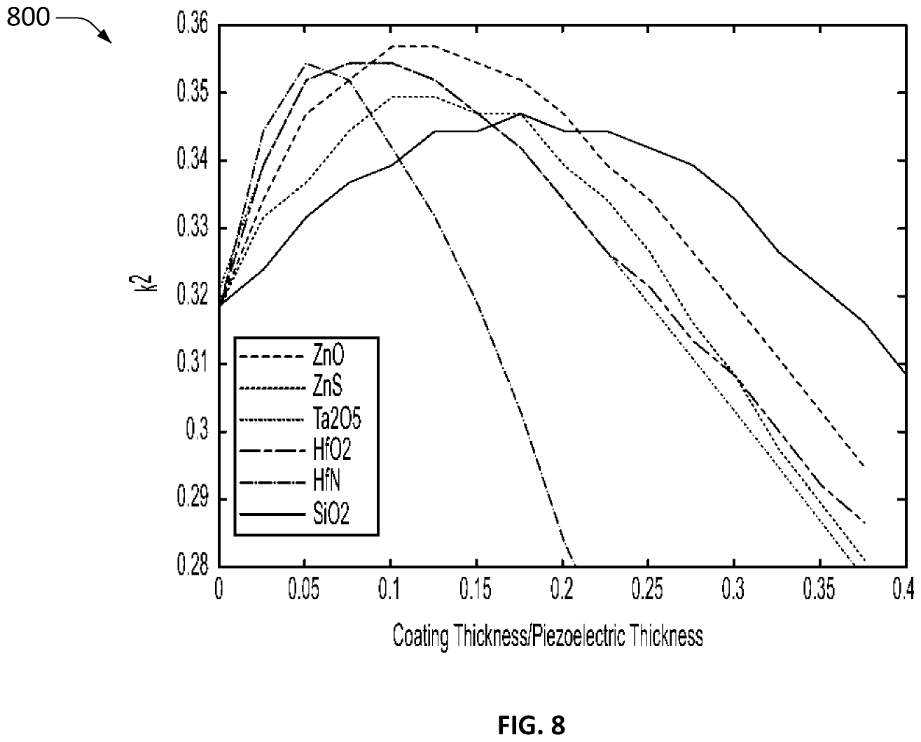

FIG. 8 shows a graph 800 of the coupling of a plurality of acoustic resonators implementing specific dielectric materials and set thicknesses according to an exemplary aspect. The data plots shown in FIG. 8 are the results of a FEM simulation performed for the acoustic resonators including symmetric coating formed of the exemplary materials for the dielectric layers as described herein. As described above, the resonator's coupling is the distance between the resonance frequency ƒᵣ and anti-resonance frequency ƒ_{α} and, for FIG. 8, is indicated by the parameter

$${k}^{2} = 1 - \frac{{f}_{r}^{2}}{{f}_{a}^{2}} .$$

It is noted that the position of ƒᵣ is usually close to the shorted (piezoelectric) plate resonance frequency, and the position of ƒ_{α} is usually close to the open (piezoelectric) plate resonance frequency.

In particular, FIG. 8 illustrates data plots for each dielectric material, i.e., ZnO, ZnS, Ta₂O₅, HfN, and HfO₂, compared with silicon dioxide as the dielectric material. As shown, an acoustic resonator having a symmetric coating of silicon dioxide has a highest coupling of 0.346 at a thickness ratio (i.e., tfd/ts) at approximately 0.18. In contrast, each of the exemplary configurations using the different materials provide for a higher coupling at a significantly lower dielectric (coating) thickness. Specifically, an acoustic resonator with a symmetric coating using ZnS as the dielectric has a peak coupling k² of 0.35 at a thickness ratio (i.e., tfd/ts) of approximately 0.125. Moreover, an acoustic resonator with a symmetric coating using HfN as the dielectric has a peak coupling k² of 0.354 at a thickness ratio (i.e., tfd/ts) of approximately 0.05. Furthermore, an acoustic resonator with a symmetric coating using Ta₂O₅ as the dielectric has a peak coupling k² of 0.354 at a thickness ratio (i.e., tfd/ts) of approximately 0.01. Similarly, an acoustic resonator with a symmetric coating using HfO₂ as the dielectric has a peak coupling k² of 0.354 at a thickness ratio (i.e., tfd/ts) of approximately 0.01. Finally, an acoustic resonator with a symmetric coating using ZnO as the dielectric has a peak coupling k² of 0.357 at a thickness ratio (i.e., tfd/ts) of approximately 0.125. Accordingly, as shown in FIG. 8, providing a symmetric coating of an acoustic resonator on each of ZnO, ZnS, Ta₂O₅, HfN, and HfO₂ provides for a higher coupling coefficient k² while significantly reducing the overall thickness of the dielectric layers and, thus, the acoustic resonator as a whole.

According to the exemplary aspects and as shown in FIG. 8, there is a symmetric coating so the dielectric thicknesses (e.g., dielectric 212 and 214 as described above) is greater than zero. For example, the starting point for the thickness ratio (i.e., tfd/ts), i.e., just at the Y axis of the graph, is 0.0025 (i.e., 0.25%). Moreover, the symmetric coating typically will have a coating such that coupling coefficient can be a maximum or slightly past the maximum, but not significantly thicker as the coupling coefficient k² drastically decreases as described herein and shown in FIG. 8. Thus, according to the exemplary aspect, the thickness ratio (i.e., tfd/ts) can be in a range from 0.25% to a percent where the coupling coefficient k² is between 0.32 and the maximum or highest coupling. As an example, an acoustic resonator having a symmetric coating with HfN has a maximum coupled of 0.354. Therefore, halfway past the peak is a coupling coefficient k² of 0.337 (i.e., 0.354+0.32/2), and, therefore, the thickness ratio (i.e., tfd/ts) is 0.12 or 12%. This is significantly thinner (and with a high coupling coefficient k²) compared with an acoustic resonator having dielectric layers formed of silicon dioxide.

Thus, according to an exemplary aspect, an acoustic resonator is provided such as the acoustic resonator shown any of FIGS. 2A, 2B and 2C having a piezoelectric layer 110 with first and second surfaces that oppose each other. Moreover, the second surface (e.g., bottom surface) is coupled to a substrate either directly or via one or more intermediate layers. The piezoelectric layer 110 includes a diaphragm over a cavity extending in at least one of the substrate (e.g., FIG. 3A) and the one or more intermediate layers (e.g., FIGS. 1B and/or 3B). In an exemplary aspect, the piezoelectric layer 110 comprises lithium niobate having Euler angles [0°, 30°, 0° ].

An interdigital transducer (IDT) is formed at the piezoelectric layer 110 that has interleaved fingers (e.g., fingers 238a and 238b) on the diaphragm. Moreover, a first dielectric layer 212 and a second dielectric layer 214 are formed on opposing surfaces of the diaphragm. The first dielectric layer 212 has a thickness tfd and the second dielectric layer 214 has a second thickness tbd, although the thicknesses tfd and tbd are the same (also referred to as a “first thickness”) in and exemplary aspect to form a symmetric coating of the diaphragm. Moreover, the first thickness of the dielectric layers 212 and 214 is (significantly) less than a thickness ts of the diaphragm of the piezoelectric layer 110. In an exemplary aspect, the acoustic resonator is configured for operating in a first-order antisymmetric (A1) mode. Moreover, the first and second dielectric layers are preferably configured for a predetermined coupling of the acoustic resonator operating in the A1 mode. In other words, a predetermined coupling can be defined, for example, by a chip designer, and then the dielectric layers can be optimized to achieve this desired coupling. Moreover, the thinner coating (compared with a thicker silicon dioxide coating) advantageously provides for better spur suppression for S2 while still obtaining a larger coupling for the A1 mode.

As described above, the first and second dielectric layers are each formed of one of ZnS, HfN, HfO₂, ZnO and Ta₂O₅. Moreover, the thicknesses of the symmetric dielectric layers are selected to achieve a desired coupling coefficient k² for the particular acoustic resonator, which is typically a maximum coupling. As will be described in more detail below, the desired coupling coefficient k² for a given acoustic resonator is predetermined or preselected in order to tune and optimized the symmetric coating. During manufacturing, the dielectric material will be selected and then deposited to a tuned thickness to obtain thickness ratio (i.e., tfd/ts) between the first thickness of the dielectric layers and the second thickness of the piezoelectric layer to obtain the predetermined coupling coefficient k².

It is noted that according to the exemplary aspect, the first thickness of the first and second dielectric layers and the second thickness of the piezoelectric layer are each measured in a direction substantially orthogonal to the opposing surfaces of the diaphragm. For example, referring back to FIG. 2A, the piezoelectric layer 110 (and the diaphragm) extend in a horizontal direction (e.g., across a cavity) and the thickness of the dielectric layers tfd and tbd as well as the thickness ts of the dielectric layer extend in a direction orthogonal thereto (e.g., in the vertical direction). It should be appreciated that the thickness direction is considered to be “substantially” orthogonal, meaning within a small tolerance of +5° or −5° (i.e., 85° to 95°) from the respective surfaces of the piezoelectric layer 110 (and the diaphragm).

In the exemplary aspect, the first thickness is between 0.25% and 22% of the second thickness when the first and second dielectric layers are ZnS. Moreover, the first thickness is between 0.25% and 12% of the second thickness when the first and second dielectric layers are HfN. Furthermore, the first thickness is between 0.25% and 21% of the second thickness when the first and second dielectric layers are HfO₂ or Ta₂O₅. Finally, the first thickness is between 0.25% and 24% of the second thickness when the first and second dielectric layers are ZnO. As described herein, these ranges of thicknesses are set to obtain a desired coupling coefficient k² that is significantly thinner than using silicon dioxide as a dielectric, but with higher coupling coefficient k².

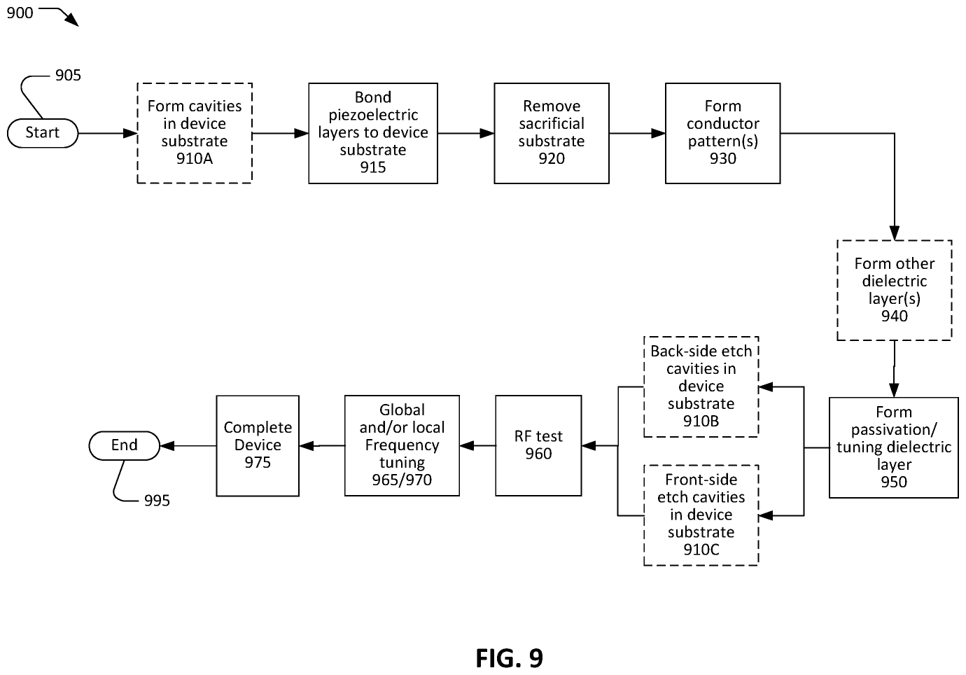

FIG. 9 illustrates a flowchart of a method of manufacturing a filter as described herein according to an exemplary aspect. In particular, method 900 summarizes an exemplary manufacturing processing for fabricating a filter device incorporating the XBARs with a symmetric coating according to an exemplary aspect. Specifically, the process 900 is provided for fabricating a filter device including multiple XBARs with the symmetric coating as described herein. The process 900 starts at 905 with a device substrate and thin layers of piezoelectric material (e.g., piezoelectric layer 110) disposed on a sacrificial substrate. The process 900 ends at 995 with a completed filter device. The flow chart of FIG. 9 includes only major process steps. Various conventional process steps (e.g., surface preparation, cleaning, inspection, baking, annealing, monitoring, testing, etc.) may be performed before, between, after, and during the steps shown in FIG. 9. It is noted that at 905, a material layer may be deposited on the piezoelectric material before it is coupled to the sacrificial substrate.

Moreover, it is noted that while FIG. 9 generally describes a process for fabricating a single filter device, multiple filter devices may be fabricated simultaneously on a common wafer (including a piezoelectric layer bonded to a substrate). In this case, each step of the process 900 may be performed concurrently on all of the filter devices on the wafer.

The flow chart of FIG. 9 captures three variations of the process 900 for making an XBAR which differ in when and how cavities are formed in the device substrate. The cavities may be formed at steps 910A, 910B, or 910C or not at all. It should be appreciated that only one or none of these steps is performed in each of the three variations of the process 900. It should be appreciated that these steps can be omitted if the filter device comprises only SM XBARs configurations, for example. In order to produce an SM XBAR having Bragg stack layer thicknesses determined according to the present disclosure, a solidly mounted XBAR may be fabricated without forming any cavities in the device substrate. An example of a solidly mounted XBAR was described above with reference to FIG. 2E.

In one variation of the process 900, one or more cavities are formed in the device substrate at 910A, before the piezoelectric layers are bonded to the substrate at 915. A separate cavity may be formed for each resonator in a filter device. Also, the cavities can be shaped and formed such that two or more resonators can be on one diaphragm over one cavity. These resonators sharing a diaphragm are acoustically coupled on an acoustic track. The one or more cavities may be formed using conventional photolithographic and etching techniques. Typically, the cavities formed at 910A will not penetrate through the device substrate.

At 915, the piezoelectric layer is bonded to the device substrate or indirectly to a dielectric layer as described above. The piezoelectric layer and the device substrate may be bonded by a wafer bonding process. Typically, the mating surfaces of the device substrate and the piezoelectric layer are highly polished. One or more layers of intermediate materials, such as an oxide or metal, may be formed or deposited on the mating surface of one or both of the piezoelectric layer and the device substrate. One or both mating surfaces may be activated using, for example, a plasma process. The mating surfaces may then be pressed together with considerable force to establish molecular bonds between the piezoelectric layer and the device substrate or intermediate material layers.

At 920, the sacrificial substrate may be removed. For example, the piezoelectric layer and the sacrificial substrate may be wafers of piezoelectric material that have been ion implanted to create defects in the crystal structure along a plane that defines a boundary between what will become the piezoelectric layer and the sacrificial substrate. At 920, the wafer may be split along the defect plane, for example by thermal shock, detaching the sacrificial substrate and leaving the piezoelectric layer bonded to the device substrate. The exposed surface of the piezoelectric layer may be polished or processed in some manner after the sacrificial substrate is detached.

A first conductor pattern, including IDTs of each XBAR and the capacitor electrodes, is formed at 930 by depositing and patterning one or more conductor layers on a front side of the piezoelectric layer (e.g., piezoelectric layer 110). The conductor layer may be, for example, aluminum, an aluminum alloy, copper, a copper alloy, or some other conductive metal. In some aspects, one or more layers of other materials may be disposed below (i.e., between the conductor layer and the piezoelectric layer) and/or on top of the conductor layer. For example, a thin film of titanium, chrome, or other metal may be used to improve the adhesion between the conductor layer and the piezoelectric layer. A second conductor pattern of gold, aluminum, copper or other higher conductivity metal may be formed over portions of the first conductor pattern (for example the IDT bus bars and interconnections between the IDTs).

Each conductor pattern may be formed at 930 by depositing the conductor layer and, in some aspects, one or more other metal layers in sequence over the surface of the piezoelectric layer. The excess metal may then be removed by etching through patterned photoresist. The conductor layer can be etched, for example, by plasma etching, reactive ion etching, wet chemical etching, or other etching techniques.

Alternatively, each conductor pattern may be formed at 930 using a lift-off process. Photoresist may be deposited over the piezoelectric layer and patterned to define the conductor pattern. It should be appreciated that the photoresist for the conductor pattern can be defined to achieve the desired chirping configurations as described above. Moreover, the conductor layer and, in some aspects, one or more other layers may be deposited in sequence over the surface of the piezoelectric layer. The photoresist may then be removed, which removes the excess material, leaving the conductor pattern.

At 940, more dielectric layers are formed on both opposing surfaces of the piezoelectric layer 110 and conductor patterns to form a symmetric coating configuration of the acoustic resonator. These layers can be deposited and trimmed to configure the resonant frequency according to exemplary aspects. As described above, material and thickness of the dielectric layers can be selected to tune the acoustic resonator for a particular coupling coefficient k². For example, if the acoustic resonator requires a coupling coefficient k² of approximately 0.337, the dielectric layers may be selected to be HfN and may then be trimmed after deposition, such that the thickness ratio (i.e., tfd/ts) is approximately 0.12 or 12% as also described above. Different materials and different thickness can be selected to provide the acoustic resonator with the predetermined and desired coupling coefficient k².

At 950, a passivation/tuning dielectric layer may be deposited over the piezoelectric layers and conductor patterns. This layer may be considered the symmetric coating in an exemplary aspect as long as the thickness ratios described above are maintained. The passivation/tuning dielectric layer may cover the entire surface of the filter except for pads for electrical connections to circuitry external to the filter. In some instantiations of the process 900, the passivation/tuning dielectric layer may be formed after the cavities in the device substrate and/or the intermediate layer are etched at either 910B or 910C.

More particularly, in a second variation of the process 900, one or more cavities are formed in the back surface of the device substrate and/or the intermediate layer at 910B. A separate cavity may be formed for each resonator in a filter device. Also, the cavities can be shaped and formed such that plurality of resonators can be on one diaphragm over one cavity. These resonators sharing a diaphragm are acoustically coupled on an acoustic track. The one or more cavities may be formed using an anisotropic or orientation-dependent dry or wet etch to open holes through the back side of the device substrate to the piezoelectric layer. In this case, the resulting resonator devices will have a cross-section as shown in FIG. 1A or FIG. 1B.

In a third variation of the process 900, one or more cavities in the form of recesses in the device substrate may be formed at 910C by etching the substrate using an etchant introduced through openings in the piezoelectric layer. A separate cavity may be formed for each resonator in a filter device. Also, the cavities can be shaped and formed such that two or more resonators can be on one diaphragm over one cavity. These resonators sharing a diaphragm are acoustically coupled on an acoustic track. The one or more cavities formed at 910C will not penetrate through the device substrate.

Ideally, after the cavities are formed at 910B or 910C, most or all of the filter devices on a wafer will meet a set of performance requirements. However, normal process tolerances will result in variations in parameters such as the thicknesses of dielectric layers formed at 940 and 950, variations in the thickness and line widths of conductors and IDT fingers formed at 930, and variations in the thickness of the piezoelectric layer. These variations contribute to deviations of the filter device performance from the set of performance requirements.

To improve the yield of filter devices meeting the performance requirements (including obtaining the desired coupling coefficient k²), frequency tuning may be performed by selectively adjusting the thickness of the passivation/tuning layer deposited over the resonators at 950. The frequency of a filter device passband can be lowered by adding material to the passivation/tuning layer, and the frequency of the filter device passband can be increased by removing material from the passivation/tuning layer. Typically, the process 900 is biased to produce filter devices with passbands that are initially lower than a required frequency range but can be tuned to the desired frequency range by removing material from the surface of the passivation/tuning layer.

At 960, a probe card or other means may be used to make electrical connections with the filter to allow radio frequency (RF) tests and measurements of filter characteristics such as input-output transfer function. Typically, RF measurements are made on all, or a large portion, of the filter devices fabricated simultaneously on a common piezoelectric layer and substrate.

At 965, global frequency tuning may be performed by removing material from the surface of the passivation/tuning layer using a selective material removal tool such as, for example, a scanning ion mill as previously described. “Global” tuning is performed with a spatial resolution equal to or larger than an individual filter device. The objective of global tuning is to move the passband of each filter device towards a desired frequency range. The test results from 960 may be processed to generate a global contour map indicating the amount of material to be removed as a function of two-dimensional position on the wafer. The material is then removed in accordance with the contour map using the selective material removal tool.

At 970, local frequency tuning may be performed in addition to, or instead of, the global frequency tuning performed at 965. “Local” frequency tuning is performed with a spatial resolution smaller than an individual filter device. The test results from 960 may be processed to generate a map indicating the amount of material to be removed at each filter device. Local frequency tuning may require the use of a mask to restrict the size of the areas from which material is removed. For example, a first mask may be used to restrict tuning to only shunt resonators, a second mask may be subsequently used to restrict tuning to only series resonators, and a third mask may be subsequently used to restrict tuning to only extracted pole resonators. This would allow independent tuning of the lower band edge and upper band edge of the filter devices.

After frequency tuning at 965 and/or 970, the filter device is completed at 975. Actions that may occur at 975 include forming bonding pads, metal traces, and/or solder bumps or other means for making connection between the device and external circuitry (if such pads were not formed at 930); excising individual filter devices from a wafer containing multiple filter devices; other packaging steps; and additional testing. After each filter device is completed, the process ends at 995.

In general, it is noted that throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. An acoustic resonator, comprising:
a substrate;
a piezoelectric layer having first and second surfaces that oppose each other with the second surface coupled to the substrate either directly or via one or more intermediate layers, the piezoelectric layer including a diaphragm over a cavity extending in at least one of the substrate and the one or more intermediate layers;
an interdigital transducer (IDT) at the piezoelectric layer and having interleaved fingers on the diaphragm; and
first and second dielectric layers on opposing surfaces of the diaphragm;
wherein each of the first and second dielectric layers have a first thickness and the piezoelectric layer has a second thickness greater than the first thickness,
wherein the first and second dielectric layers each comprise one of ZnS, HfN, HfO₂, ZnO and Ta₂O₅,
wherein the first thickness is between 0.25% and 22% of the second thickness when the first and second dielectric layers are ZnS,
wherein the first thickness is between 0.25% and 12% of the second thickness when the first and second dielectric layers are HfN,
wherein the first thickness is between 0.25% and 21% of the second thickness when the first and second dielectric layers are HfO₂,
wherein the first thickness is between 0.25% and 24% of the second thickness when the first and second dielectric layers are ZnO, and
wherein the first thickness is between 0.25% and 21% of the second thickness when the first and second dielectric layers are Ta₂O₅.

2. The acoustic resonator according to claim 1, wherein the IDT is on the first surface of the piezoelectric layer and the first dielectric layer is on and between the interleaved fingers of the IDT.

3. The acoustic resonator according to claim 1, wherein the IDT is on the second surface of the piezoelectric layer and the second dielectric layer is on and between the interleaved fingers of the IDT.

4. The acoustic resonator according to claim 1, wherein the first and second dielectric layers comprises a symmetric coating thickness on the opposing surfaces of the diaphragm.

5. The acoustic resonator according to claim 1, wherein the one or more intermediate layers comprise silicon dioxide.

6. The acoustic resonator according to claim 1, wherein the acoustic resonator is configured for operating in a first-order antisymmetric (A1) mode and the first and second dielectric layers are configured for a predetermined coupling of the acoustic resonator operating in the A1 mode.

7. The acoustic resonator according to claim 1, wherein the piezoelectric layer comprises lithium niobate having Euler angles [0°, 30°, 0° ].

8. The acoustic resonator according to claim 1, wherein the piezoelectric layer and the IDT are configured such that a radio frequency signal applied to the IDT excites a primary shear acoustic mode in the diaphragm that is a bulk shear mode where acoustic energy propagates along a direction substantially orthogonal to the first and second surfaces of the piezoelectric layer and transverse to a direction of electric field created by the IDT.

9. The acoustic resonator according to claim 1, wherein the first thickness of the first and second dielectric layers and the second thickness of the piezoelectric layer are each measured in a direction substantially orthogonal to the opposing surfaces of the diaphragm.

10. An acoustic resonator, comprising:
a piezoelectric layer having first and second surfaces that oppose each other;
an interdigital transducer (IDT) at the first surface of the piezoelectric layer;
a first dielectric layer on the first surface of the piezoelectric layer and on and between interleaved fingers of the IDT; and
a second dielectric layer on the second surface of the piezoelectric layer that is opposite to the first dielectric layer,
wherein each of the first and second dielectric layers comprise a same material comprising one of ZnS, HfN, HfO₂, ZnO and Ta₂O₅, the first and second dielectric layers each having a same first thickness to form a symmetric coating configuration on the piezoelectric layer,
wherein the piezoelectric layer has a second thickness greater than the first thickness,
wherein the first thickness is between 0.25% and 22% of the second thickness when the first and second dielectric layers are ZnS,
wherein the first thickness is between 0.25% and 12% of the second thickness when the first and second dielectric layers are HfN,
wherein the first thickness is between 0.25% and 21% of the second thickness when the first and second dielectric layers are HfO₂,
wherein the first thickness is between 0.25% and 24% of the second thickness when the first and second dielectric layers are ZnO, and
wherein the first thickness is between 0.25% and 21% of the second thickness when the first and second dielectric layers are Ta₂O₅.

11. The acoustic resonator according to claim 10, further comprising a substrate and one or more intermediate layers that couple the piezoelectric layer to the substrate.

12. The acoustic resonator according to claim 11, wherein the piezoelectric layer includes a diaphragm over a cavity that extends in at least one of the substrate and the one or more intermediate layers.

13. The acoustic resonator according to claim 12, wherein the first surface of the piezoelectric layer faces away from the cavity.

14. The acoustic resonator according to claim 11, wherein the one or more intermediate layers comprise silicon dioxide.

15. The acoustic resonator according to claim 10, wherein the acoustic resonator is configured for operating in a first-order antisymmetric (A1) mode and the first and second dielectric layers are configured for a predetermined coupling of the acoustic resonator operating in the A1 mode.

16. The acoustic resonator according to claim 10, wherein the piezoelectric layer comprises lithium niobate having Euler angles [0°, 30°, 0° ].

17. The acoustic resonator according to claim 10, wherein the piezoelectric layer and the IDT are configured such that a radio frequency signal applied to the IDT excites a primary shear acoustic mode in a diaphragm of the piezoelectric layer that is a bulk shear mode where acoustic energy propagates along a direction substantially orthogonal to the first and second surfaces of the piezoelectric layer and transverse to a direction of electric field created by the IDT.

18. The acoustic resonator according to claim 10, wherein the first thickness of the first and second dielectric layers and the second thickness of the piezoelectric layer are each measured in a direction substantially orthogonal to the first and second surfaces of the piezoelectric layer.

19. A method of fabricating an acoustic resonator device having a dielectric layer configured to optimize electromechanical coupling, the method comprising:
attaching a piezoelectric layer to a substrate via one or more intermediate layers to form a diaphragm over a cavity in the one or more intermediate layers;
forming an interdigital transducer (IDT) at the piezoelectric layer;
depositing first and second dielectric layers on opposing surfaces of the diaphragm, such that at least one of the first and second dielectric layers is on and between interleaved fingers of the IDT, with the first and second dielectric layers formed of a same material comprising one of ZnS, HfN, HfO₂, ZnO and Ta₂O₅; and
trimming the first and second dielectric layers to form a symmetric coating on the diaphragm, such that the first and second dielectric layers have a first thickness that is less than a second thickness of the piezoelectric layer,
wherein the trimming of first and second dielectric layers provides for the first thickness to be between 0.25% and 22% of the second thickness when the first and second dielectric layers are ZnS,
wherein the trimming of first and second dielectric layers provides for the first thickness to be between 0.25% and 12% of the second thickness when the first and second dielectric layers are HfN,
wherein the trimming of first and second dielectric layers provides for the first thickness to be between 0.25% and 21% of the second thickness when the first and second dielectric layers are HfO₂,
wherein the trimming of first and second dielectric layers provides for the first thickness to be between 0.25% and 24% of the second thickness when the first and second dielectric layers are ZnO, and
wherein the trimming of first and second dielectric layers provides for the first thickness to be between 0.25% and 21% of the second thickness when the first and second dielectric layers are Ta₂O₅.

20. The method according to claim 19, wherein the piezoelectric layer and the IDT are configured such that a radio frequency signal applied to the IDT excites a primary shear acoustic mode in the diaphragm that is a bulk shear mode where acoustic energy propagates along a direction substantially orthogonal to the opposing surfaces of the diaphragm and transverse to a direction of electric field created by the IDT.
